(19) United States
(12) Patent Application Publication
(10) Pub. No.: US 2024/0199451 A1
(43) Pub. Date: Jun. 20, 2024

(54) Apparatus for Treating Water using a Plasma Source that is Protected from Water

(71) Applicant: The Board of Trustees of the Leland Stanford Junior University, Stanford, CA (US)

(72) Inventors: Benjamin Wang, Cary, NC (US); David B. Rogers, Pasadena, CA (US); Mark A. Cappelli, Sunnyvale, CA (US)

(21) Appl. No.: 18/287,290

(22) PCT Filed: Apr. 28, 2022
(86) PCT No.: PCT/US2022/026757

§ 371 Date: Oct. 17, 2023

Related U.S. Application Data
(60) Provisional application No. 63/180,981, filed on Apr. 28, 2021.

(51) Int. Cl. C02F 1/46; B01J 19/00; B01J 19/08; C01D 9/00; C02F 1/66; C02F 1/68; C02F 103/02; C05C 1/00; H05H 1/24

(52) U.S. Cl. CPC C02F 1/4608; B01J 19/0013; B01J 19/088; C01D 9/00; C02F 1/66; C02F 1/68; C05C 1/00; H05H 1/2406; B01J 2219/0837; B01J 2219/0869; B01J 2219/0871; B01J 2219/0877; B01J 2219/0896; C02F 2103/02; H05H 2242/10; H05H 2245/20

(57) ABSTRACT

Apparatus for treating water is provided where the apparatus includes a reaction chamber having an air-water interface and a plasma applicator disposed in air in proximity to the air-water interface. The plasma applicator includes a solid dielectric plate sandwiched between a first electrode and a second electrode, where the first electrode is closer to the water than the second electrode. The plasma applicator further includes a first insulating layer disposed on the first electrode. The apparatus is configured to generate a plasma between the first insulating layer and the air-water interface during operation.

### FIELD OF THE INVENTION

This invention relates to plasma treatment of water.

### BACKGROUND

Nitrogen is a key component of fertilizer and is essential to plant growth and health. Currently, most nitrogen in fertilizers is available in solid form, often as a nitrogen-containing chemical group bound to a chemical carrier. For example, the most common nitrogen fertilizer is ammonium nitrate, which is a nitrate chemical group (NO₃⁻) bound to ammonium (NH₃—H), or as urea, two amino radicals (NH₂), bound to carbon monoxide (CO). Both ammonium nitrate and urea are highly soluble in water. These common nitrogen fertilizers are mostly manufactured using the Haber-Bosch process. However, both the steam methane reforming to produce the H₂ required by the Haber-Bosch process and the Haber-Bosch process itself are energy-intensive and contribute to greenhouse gas emissions. For example, about 2% of global energy consumption and about 2% of anthropogenic carbon dioxide (CO₂) emissions is directly attributable to fertilizer production. The harmful consequences of these traditional means of “fixating” nitrogen, i.e., producing compounds of nitrogen where the nitrogen atom is chemically attached with a single bond, illustrate the need for alternative processes for producing fertilizers. Accordingly, it would be an advance in the art to provide improved nitrogen fixation.

### SUMMARY

This work provide apparatus for producing water-dissolved nitrates, i.e., similar to what is obtained when ammonium nitrate is dissolved in water, using just water, ambient air, and electricity. An air plasma is produced using a gas discharge, and the exposure of this plasma to a shallow water channel flow enriches water with dissolved nitrates.

A gas discharge plasma, when generated in a molecular gas such as air, is composed of electrons, positive and negative ions, excited and neutral atoms, and other reactive molecular species and radicals. Plasma fixation of nitrogen in water, sometimes referred to as “plasma-activated water,” can be generated via air plasma treatment either above or directly in water (i.e., the water is exposed to a plasma stream, or a plasma is generated directly in the water). Such an activation results in the formation of numerous dissolved and chemically active species, often generalized as reactive oxygen and nitrogen species (RONS).

There are several scientific studies that describe processes that treat water with a plasma by (i) exposing the plasma to a free water surface; (ii) produce a plasma directly in water; or (iii) produce a plasma in wither water vapor or mixed water phases (e.g., water mists). Some of these studies use pure air and some use small amounts of air diluted in a carrier gas that is not air. The plasma activates the air-containing gas, or the water itself, and these active species react with the water to become solvated (dissolved) species reactive species. These dissolved species can form nitrates. In addition to nitrates, dissolved species can also include nitrites and peroxides, among others.

When plants are irrigated with this activated water, the nitrates are taken up by the plant roots, and serve as a source of nitrogen to promote plant growth. Production of nitrate ions in water for use as an exogenous fertilizer source is provided. The application of plasma-fixated nitrogen in agriculture has recently gained much attention because of its various interesting properties and potential for sustainable production. In the literature, there is evidence that plasma activated water has been shown to enhance seed germination, plant growth, and that it may also have antiseptic properties as a result of microbial reduction. In this work, we also show that this approach produces an activated water that has a high degree of efficacy by comparing its use to more commonly used fertilizers in treating common turf grass, specifically rye grass and bent grass.

We examine the use of plasma-fixated nitrogen in the fertilization of turf grass because turf grass is considered to be one of the largest irrigated crops in the United States, covering a greater surface area than even irrigated corn. Turf grass is commonly used in residential and commercial lawns, golf courses, and recreational and sports fields. As such, turf grass has the potential to sequester a large amount of excess carbon from the atmosphere and reduce greenhouse gas emissions. The use of sustainable energy in the production of plasma-fixated nitrogen for turf grass growth would further reduce its carbon footprint. This approach for producing plasma activated water in concentrated forms, particularly for recreational fields, and its dispensing into irrigation systems may be uniquely suited to the fertilization of turf grass because of the regular rate of irrigating turf grass. Our results of studies on turf grass also support the use of this plasma-produced fertilizer on agricultural food crops. As described herein, it can be packaged as an appliance of varying size to produce the nitrogen needed for a particular application, enabling the decentralized production of nitrogen. Smaller units can also be manufactured in large numbers and assembled together to produce large-scale manufacturing centers.

Several embodiments described below make use of a chamber in which air (or modified air) is admitted. This air is exposed to a plasma formed by the electrification of a plasma applicator. The chamber also provides a means of introducing the water to be treated. In one embodiment, all of the water to be treated occupies the same chamber at all times. In another embodiment, the water may be transitory, i.e., flows into or out of the chamber in one or more passes, with a large amount of this water stored in a vessel for recirculating through the plasma treatment chamber. In yet another embodiment, the air that is treated by the plasma leaves the chamber and is discarded. In yet another embodiment, the air that is treated by the plasma is reintroduced back into the same chamber, or into the chamber of another fertilization unit. In a further embodiment, the treated air can be bubbled through the water that is being treated, or being stored for treatment and retreatment. In some embodiments, the air drawn from an ambient source can also enter a device that enhances its oxygen content to provide oxygen enriched conditions.

The present approach also allows for the water that is being treated to be controlled in temperature, sometimes higher than ambient to encourage the chemical reactions in the water phase, particularly so when activated air is being recirculated and bubbled through the water to further enhance the capturing of reactive nitrogen. This recirculated air increases the probability of the capture of nitrogen oxides by the water, thereby decreasing the amount of nitrogen oxides that are released into the exhaust and subsequently the environment.

The plasma applicator belongs to a family of so-called dielectric barrier discharges (DBDs) but differs from conventional designs in several important respects, as described in greater detail below.

Applications of this work include the fertilization of water, as described below. It can also be used to sterilize/disinfect water, e.g., by acidifying water to lower its pH. Likely consumers would be agricultural facilities, particularly specialty farms, hydroponic facilities, and indoor farms. Other applications include the maintenance of landscaped parks and athletic recreational areas such as football and baseball fields and the grasses and greens of other sporting venues.

### BRIEF DESCRIPTION OF THE DRAWINGS

FIG. 1 shows an exemplary embodiment of the invention.

FIG. 2 is an enlarged view of a plasma applicator suitable for use in embodiments of the invention.

FIGS. 3A-C show various gas handling options for the embodiment of FIG. 1.

FIGS. 4A-B show exemplary bottom electrode configurations for the plasma applicator.

FIG. 5 shows another embodiment of the invention.

FIGS. 6A-D show various gas handling options for the embodiment of FIG. 5.

FIGS. 7-9 show results from an experiment on plasma activation of water.

FIGS. 10A-B show plant growth height and mass results for various dilutions of plasma activated water.

FIGS. 11A-B show plant growth height and mass results for plasma activated water versus controls.

FIGS. 12A-B show plant growth height and mass results for plasma activated water versus other sources of nitrogen.

### DETAILED DESCRIPTION

Section A describes general principles relating to embodiments of the invention, and section B is a more detailed description of some exemplary embodiments.

### A) General Principles

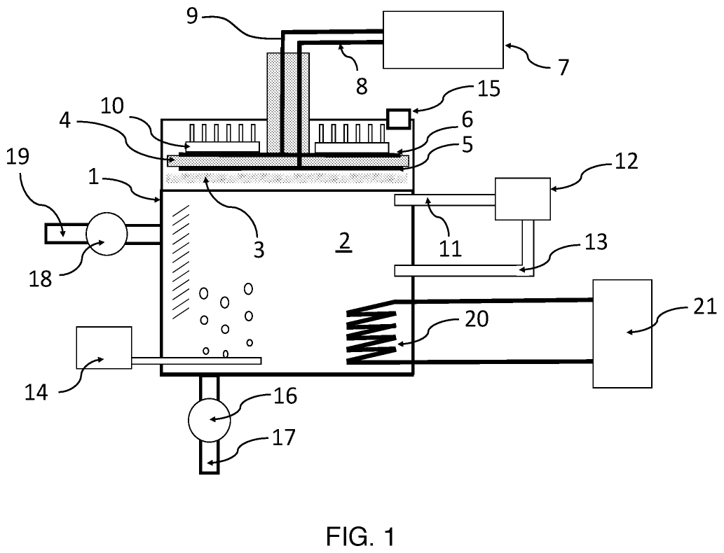

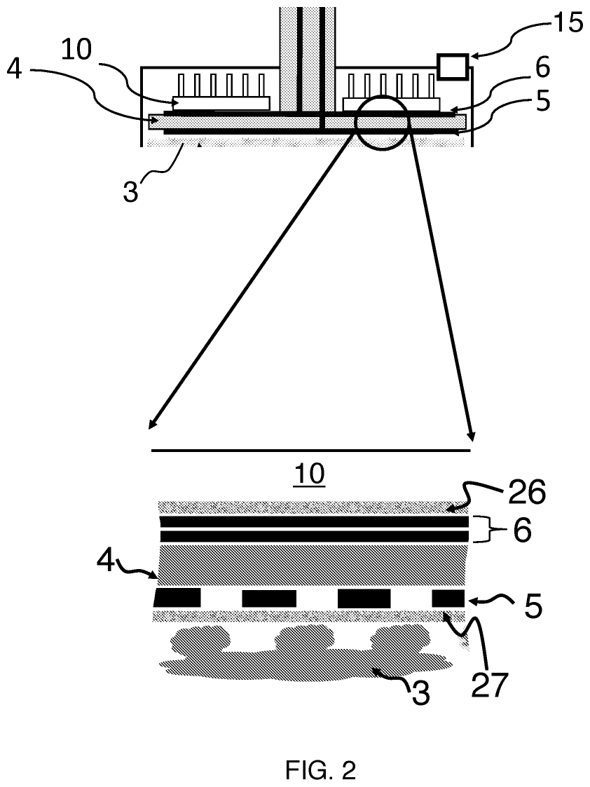

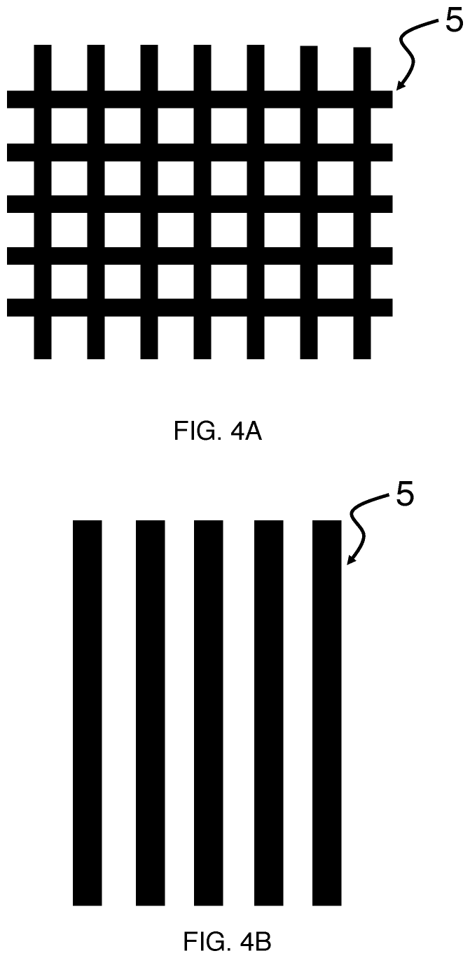

An exemplary embodiment of the invention is an apparatus for treating water, where the apparatus includes:
1) a reaction chamber (e.g., 1 on FIG. 1, 61 on FIG. 5) having an air-water interface; and
2) a plasma applicator (e.g., 67 on FIG. 5, FIG. 2) disposed in air in proximity to the air-water interface, where the plasma applicator includes a solid dielectric plate (e.g., 4 on FIGS. 1 and 2) sandwiched between a first electrode (e.g., 5 on FIGS. 1 and 2) and a second electrode (e.g., 6 on FIGS. 1 and 2), where the first electrode is closer to the water than the second electrode, and where the plasma applicator further includes a first insulating layer (e.g., 27 on FIG. 2) disposed on the first electrode.

The apparatus is configured to generate a plasma between the first insulating layer and the air-water interface during operation, e.g., as shown on FIGS. 1 and 2.

The apparatus can be configured to provide nitrogen in water as nitrates and/or nitrites. The apparatus can be configured to acidify water.

The plasma preferably has an electron energy range from 1 eV to 10 eV and a gas temperature of 1000° C. or less, where this gas temperature applies to all ionized and neutral molecular and/or atomic species in the plasma). In other words the ‘gas temperature’ is the temperature of everything in the plasma except the electrons. Such a plasma is non-thermal because the electrons are heated to a temperature higher than the gas temperature.

The first electrode can be configured in various patterns, including but not limited to: square meshes, rectangular meshes, triangular meshes, hexagonal meshes and 1D arrays of elements.

The reaction chamber can be configured as a water reservoir, as in the example of FIG. 1. Alternatively, the reaction chamber can be configured as a flow chamber through which water from a reservoir is pumped, as in the example of FIG. 5.

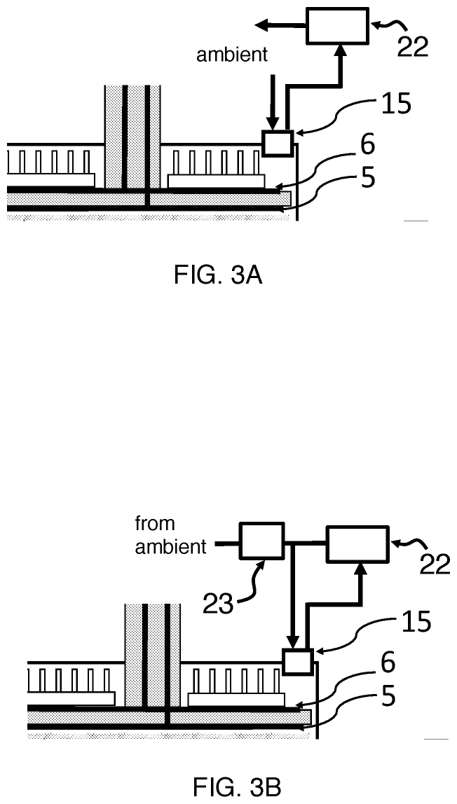

The apparatus can further include a gas circulation system. The gas circulation system can be configured to bubble air containing activated chemical species from the plasma through the water. The gas circulation system can be configured to provide oxygenated air to the plasma. See FIGS. 3A-D and 6A-D for examples.

The apparatus can further include a heat sink affixed to the plasma applicator. In such a case, the apparatus can further include a second insulating layer (e.g., 26 on FIG. 2) sandwiched between the second electrode and the heat sink.

### B) Detailed Examples

FIG. 1 shows a first exemplary embodiment. This example includes a large vessel 1, preferably made of materials that can withstand acidic and reactive (oxidizing) environments such as stainless-steel, filled with a fluid 2 that is predominantly water (i.e., 95% or more by weight H₂O). For simplicity, fluid 2 is also referred to as ‘water 2’ in this description, even though it can be well water, sea water, city water etc. The free surface of the water is exposed to a sheet of nonequilibrium plasma 3. The plasma is formed by driving a displacement current across a dielectric plate 4 made of materials such as alumina, common polymers, or even common dielectric composites such as FR4 (a common RF substrate). The dielectric has a lower metallic electrode 5 and upper electrode 6 that are connected to an electrical power generator 7 to produce the plasma. The combination of the dielectric plate and electrodes that are connected to the generator is herein referred to as a “plasma applicator.” The range of frequencies that can be used to drive this applicator is between 5 kHz and 50 MHz depending on the particular materials that are used in the applicator for its construction. The power generator is connected to the electrodes by electric cables 8 and 9. One of the electrodes, preferably the upper electrode, can be grounded but this is not required. It is possible that some of the energy delivered to the plasma applicator from power generator 7 is dissipated as heat. This heat can be conducted away from the plasma applicator using a heat sink 10 to maintain a safe applicator temperature.

A pump 12, preferably one that is resistant to chemical attack, can draw processed water near the interface between the water and the plasma using a draw line 11, and return it to the tank using a return line 13, recirculating the water to provide for mixing the processed water with the unprocessed water. This can provide mixing to prevent kinetic saturation of the activated interfacial region. It also provides for a redistribution of heated water as the water near the surface increases in temperature during processing. A second pump 14 can serve as a bubbler to introduce additional dissolved air to the water processed in the tank. One or more ports 15 serve to regulate the air that is processed by the plasma at the plasma-water interface, allowing new air to enter or leave as desired. These ports can be made to be variable in size, depending on the amount of water processed in the tank. The circulation of this air through these ports can be assisted by a blower (not shown). A valve 16 connected to a drain tube 17 can provides a way to transfer processed water into storage bins. A second access port 18 can be used to accommodate various types of sensors (for pH, nitrates, temperature), by diverting some of the processed water over to a small secondary tube appendage 19 filled with static processed water.

The system can be equipped with a means of regulating the water temperature. A temperature control element 20, serviced by an heating/cooling source 21, can be used to add and/or remove heat to raise, lower and/or control the temperature of the process water if so desired to enhance product yield. For example, 20 can include heating and/or cooling elements, and 21 can include an electrical power supply and/or a compressor unit.

The size of the tank 1 is variable. It might be 50 liters, or even 500 liters. The power of the plasma applicator can be 100 W or even 1 kW. For larger tanks, an array of applicators can be used to provide a large enough plasma sheet to fill the free surface of the water in the tank. The nitrate concentration in the water can range from very low values, such as 0 ppm, to very high values (10,000 ppm) and higher. The pH can range from values of 8, down to values of 0.8, representing the formation of processed water that is of moderate acidity. We anticipate that these lower levels of acidity will cause the evolution of absorbed carbon dioxide, CO₂. As a side benefit, this approach can also be used to therefore capture CO₂ from water.

The plasma applicator is designed to be able to be in very close proximity of the water and sufficiently robust and immune to failure as a result of the possibility that water condenses or splashes on the applicator. An important embodiment is the use of a compound dielectric barrier discharge that is free of any direct contact between the metal and the plasma. An expanded view of the plasma applicator illustrated in FIG. 1, is shown in FIG. 2. The cross section of the applicator reveals a metal heat sink 10 which may or may not have fins to regulate the temperature of the dielectric barrier 4. Since it may be desirable to have the upper electrode layer 6 below the heat sink 10 to be powered, a thin dielectric layer 26, including materials such as a polymer, mica, and even a glass layer (of one of many glass compositions) is used to electrically isolate the upper electrode 6 from the heat sink 10. The upper electrode itself may include multiple metallic layers to enhance adhesion and control thermal mismatches between electrode 6 and dielectric layer 26.

The most important feature on FIG. 2 is that the lower electrode 5 is covered with a thin dielectric layer 27, preferably glass, e.g. as described above in connection with layer 26. In conventional dielectric barrier discharges, the lower electrode 5 is not covered. The thin dielectric layer 27 here serves to isolate the lower electrode from the water. Despite the covering of the lower electrode 5 with a dielectric layer 27, a plasma still forms on the lower surface of layer 27 when the thickness and properties of layer 27 are chosen to be such that the capacitance of layer 27 is much greater than the capacitance of the dielectric plate 4. Under these conditions, the voltage drop across layer 27 will be small in comparison to the voltage drop across the dielectric plate 4 and, the electrostatic potential at the lower surface of layer 27 will be sufficiently high, relative to that of the distant air, to excite and ionize the air in the immediate vicinity of layer 27.

The ambient air that enters the chamber via port 15 on FIG. 1 can be drawn through the chamber by a downstream pump/blower 22 and released back to ambient as shown in the more detailed expanded view of FIG. 3A. Note that the proximity of the inlet and outlet in port 15 is arbitrary and they can be near or far from each other. In another embodiment, as depicted in FIG. 3B, the air that is drawn from the chamber by the pump/blower 22 is returned to the inlet line for recycling into the chamber. Air enters from ambient via the valve 23 to make up for the deficit from air that is lost from the chamber during processing. The benefit of this embodiment is that metastable reactive species such as ozone (03) or nitrogen oxides (NOₓ, where x=1, 2), produced within the chamber, will be returned to the chamber for further reaction with the water surface.

In yet another embodiment, as illustrated in FIG. 3C, the system can instead direct the air that leaves the port 15 using the pump/blower 22 to the bubbler (14 in FIG. 1). In this variation, instead of bubbling ambient air into the water being processed, air that is activated by the plasma is bubbled through the water. This air can contain the reactive components described above to further activate the water.

Yet another embodiment is shown on FIG. 3D. In this embodiment, deficit air that is drawn into the recirculation loop is drawn from an oxygenating unit 24, which produces a stream of oxygenated air, with concentrations ranging from the nominal 22% O₂/78% N₂, up to 90% O₂/10% N₂. The oxygenating unit can also be introduced in place of the valve 22 in FIG. 3C for providing a source of oxygen enhanced air in the recirculation loop. The addition of high concentrations of oxygen, above that found in ambient air, serves to enhance the chemical formation of O₃ and NO, both of which serve to form important nitrogen-containing reactive intermediates which are more easily dissolved in the water. In the example of FIG. 3D, a path from 02 source 24 to the bubbler is shown, since embodiments can use various combinations of valves (not shown) and piping to provide various gas handling functions. For example, oxygen from source 24 can be provided to both the plasma and to the bubbler.

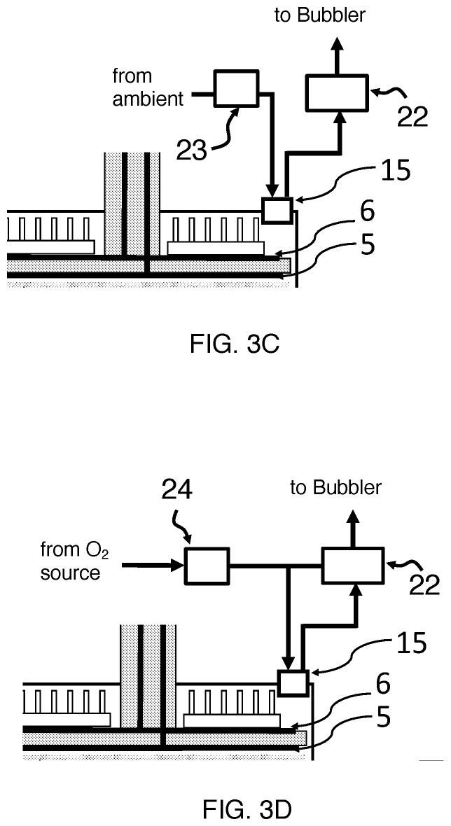

The lower electrode 5 can be a structured metallic pattern that is screen printed, electroplated, or sputtered onto the lower surface of the dielectric. The particular pattern, examples of which may be square (as shown in FIG. 4A), or stripes (as shown in FIG. 4B), depends on a number of factors such as power density that is deposited into the air, the frequency of the plasma generator, and the composition of the air. Typically, at lower frequencies (i.e., 5 kHz to 1 MHz) a “mesh” pattern, e.g. as shown on FIG. 4A, is preferable, while at higher frequencies (i.e., 1 MHz to 50 MHz) a “slat” pattern, e.g. as shown on FIG. 4B, is preferable. The patterns contribute to the impedance of the applicator, which is the load that is presented to the high frequency power generator. Good impedance matching is preferred for efficient transfer of power from the generator to the applicator.

An alternate embodiment is shown in FIG. 5. This approach is more amenable to scaling production to process large volumes. In FIG. 5, the reservoir of the water to be nitrated is separated from the process plasma device. The reservoir can be a large tank 51 that may in itself be filled and drained by drawing water 52 from a source. If desired, a bubbler 53 can be used in the large tank to aerate the water. A heater or chiller 54 can be used to regulate the temperature of the water in the tank, possibly heating or cooling the water to enhance the plasma reactions with the water. A pump 55, preferably one that is resistant to acids and corrosion, together with valves 56 and 57, is used to draw water from the tank 51 delivering it using piping 58 to the air-tight plasma process unit 61 and returning it to the tank via piping 60. When delivered to the plasma process unit 61, the water is introduced into a platen 59 which supports a water channel flow of depth of a few millimeters or less. Fresh air or other process gases can enter and be processed and can leave the process unit via intake port 63 and exhaust port 62, respectively.

A plasma 64 is produced on top of the water's free surface as it flows within a channel inside this plasma process unit. The plasma is formed by a similar applicator as shown in FIG. 2 above. As above, the plasma is formed by driving a displacement current across a dielectric plate. A lower metallic electrode or upper metallic electrode are driven by an alternating-cycle power generator to produce the plasma. The metal-dielectric-metal assembly is shown here as a single unit 67, which is attached to a liquid-cooled plate 66. A chilled fluid such as water but possibly other fluids, circulates through this plate using appropriate plumbing and returns to the refrigeration unit 65. The plasma power supply 68 is attached to the upper surface of the cooled plate 66 which serves to remove heat from power supply 68. High voltage lines 69 pass through this chilled plate to make contact with the upper and lower metallic plates of the plasma applicator 67.

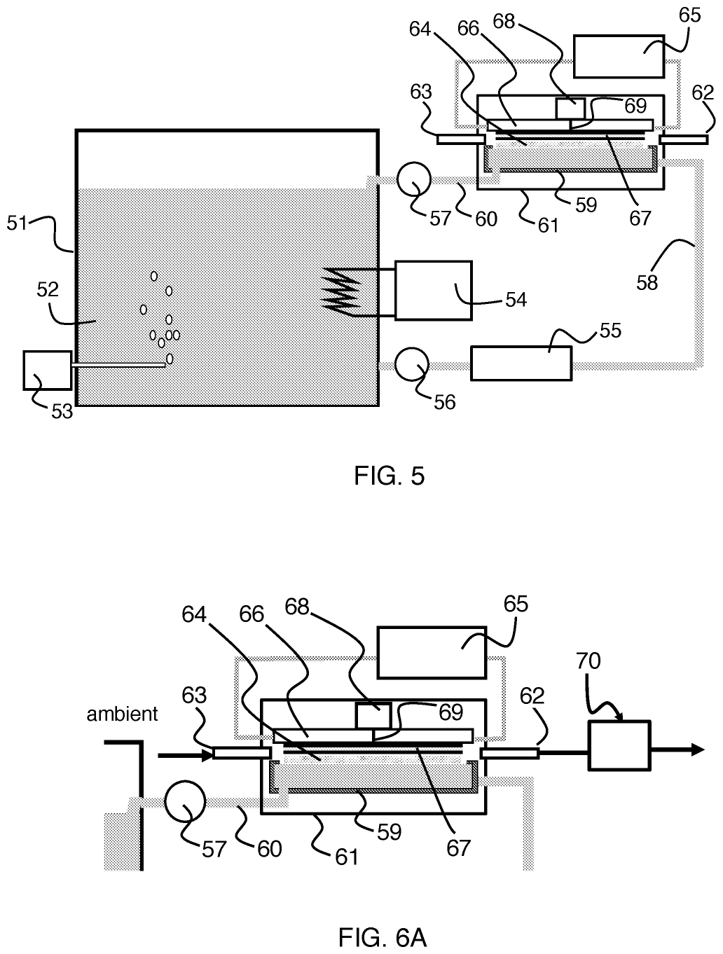

Similar modifications to the design of FIG. 5 can be implemented, to recirculate processed air, or to use oxygen enhanced air, as described above in reference to the inlet/outlet air ports of the design described in FIG. 1. An expanded view of the process chamber of FIG. 5 is reproduced in FIGS. 6A-D. The air that enters the chamber via intake port 63 is drawn into the chamber from the ambient near 63 by a pump/blower 70 via exhaust port 62 as shown in FIG. 6A.

In another embodiment, as depicted in FIG. 6B, the air that is drawn from the chamber by the pump/blower 70 is returned to the inlet line for recycling into the chamber. Air enters from ambient via the valve 71 to make up for the deficit from air that is lost from the chamber during processing. As before, the benefit of this embodiment is that metastable reactive species such as ozone (03) or nitrogen oxides (NOₓ, where x=1, 2), produced within the chamber, will be returned to the chamber for further reaction with the water surface.

In yet another embodiment, as illustrated in FIG. 6C, the system can instead direct the air that leaves the exhaust line 62 using the pump/blower 70 to the bubbler (53 on FIG. 5). In this variation, instead of bubbling ambient air into the water being processed, air that is activated by the plasma is bubbled through the water. This air can contain the reactive components described above to further activate the water.

Yet another embodiment is shown on FIG. 6D. In this embodiment, deficit air that is drawn into the loop is drawn from an oxygenating unit 74, which captures nitrogen to produce a stream of oxygenated air, with concentrations ranging from the nominal 22% O₂/78% N₂, up to 90% O₂/10% N₂. The oxygenating unit 74 can also be introduced in place of the valve 71 in FIG. 6C for providing a source of oxygen enhanced air in the recirculation loop. As mentioned above, the addition of high concentrations of oxygen, above that found in ambient air, serves to enhance the chemical formation of O₃ and NO, both of which serve to form important nitrogen-containing reactive intermediates which are more easily dissolved in the water. In the example of FIG. 6D, a path from 02 source 74 to the bubbler is shown, since embodiments can use various combinations of valves (not shown) and piping to provide various gas handling functions. For example, oxygen from source 74 can be provided to both the plasma and to the bubbler.

Another embodiment has these plasma processing units described in FIGS. 5 and 6A-D attached to each other, in series, so that the nitrated water leaving one unit can enter the other for further processing. Alternatively, they can be connected in parallel so that the water delivered from the reservoir is split into multiple streams which enter multiple process units in parallel. The processed water then rejoins together to return to the main reservoir. When cycled through the processing unit and returned several times, the nitrate concentration builds up to potentially high levels, as high as 2500 ppm and even higher, such as 10,000 ppm. This concentrated fertilized water can be diluted with non-fertilized water to a desired level for applications.

In various experiments, we have fabricated several small and large versions of devices as shown in FIGS. 1-2, to process volumes of water ranging from 0.1 liters to 50 liters, and with investments of energy ranging from 0.001 Megajoules to 10 Megajoules. We have tested the variations of this device for their ability to form dissolved nitrates and concomitantly to lower the pH of the water. These results demonstrate the capability of the plasma applicator as described herein to provide nitrogen activated water, despite the inevitable reduction of available plasma discharge power that is deposited into the air caused by the bottom insulating layer (27 on FIG. 2).

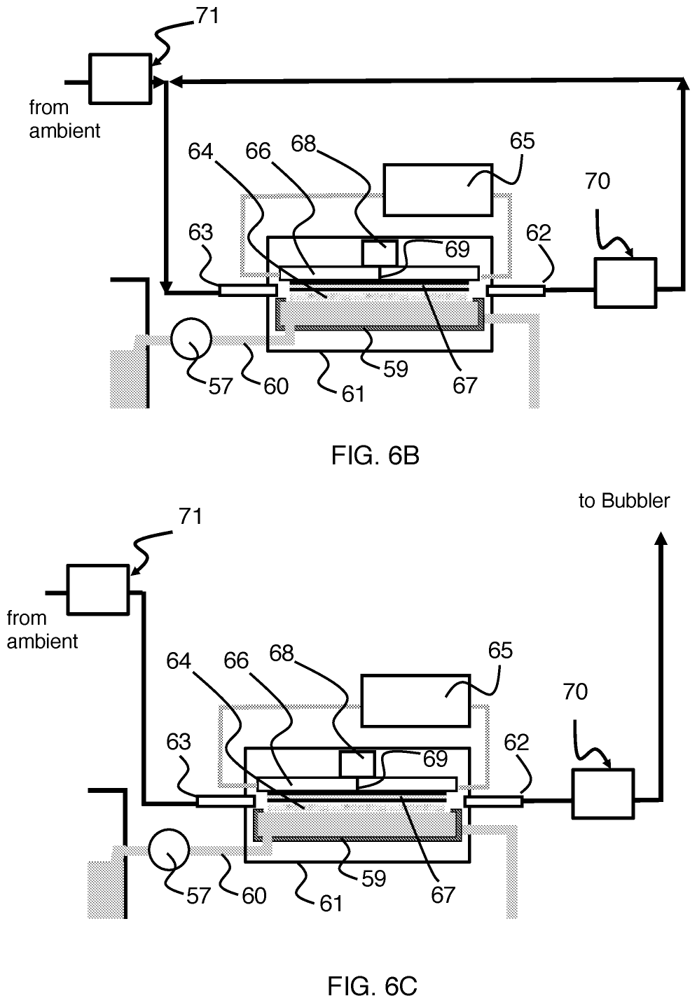

FIGS. 7-9 shows the results of one particular study of a system that was operational for almost 14 hours processing nearly 50 liters of water. The system operated stably, and was turned on and restarted three times to illustrate its ability to reproduce its quasi-steady operating conditions. The system could have run indefinitely as there was no need to refurbish components. As one can see from the figures, longer operating times resulted in high concentrations of dissolved radicals in solution.

FIG. 7 shows the formation of nitrates (in mg/l) for this particular study. The plot shows three concatenated curves due to the three successive, approximately 4-5 hour tests on the same batch of water. The tests were separated at times by several days during which the temperature dropped to room temperature and some expected settling of the solution occurred. We see that the rate of production is reproducible, and that the nitrate concentration does not decay substantially between runs after an initial period of mixing of the settled water occurs. The initial inflections over approximately 1000 seconds in the beginning of the second and third run is a result of this settling of the fluid from the previous run

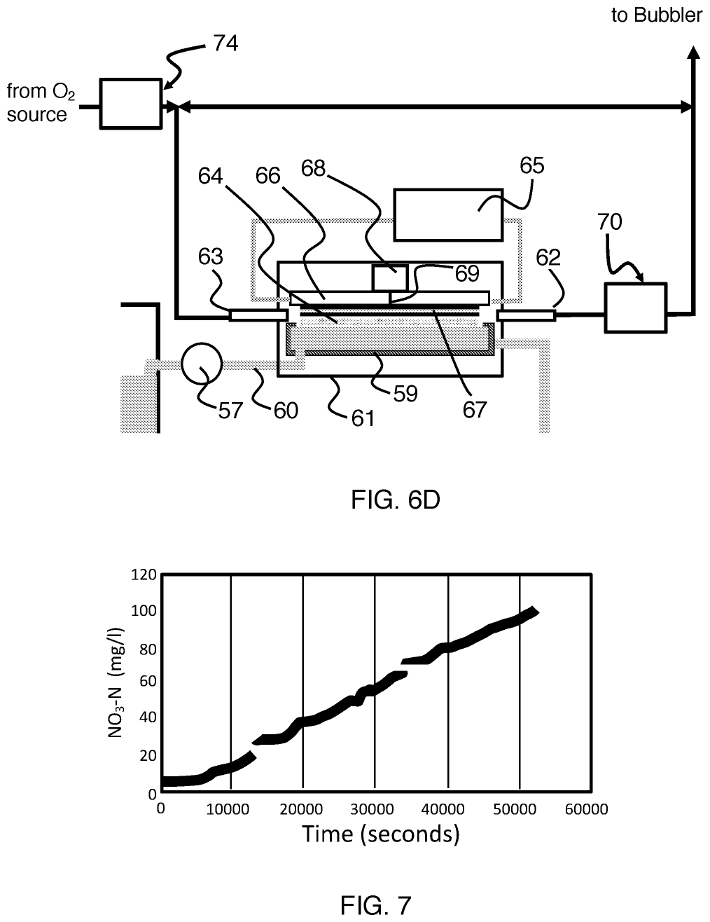

FIG. 8 shows the pH of the water as it is treated. We see that the pH drops strongly at first and then gradually, largely because of the logarithmic dependence of pH on concentrations of ions in solution. The drop is a further confirmation of the formation of nitrates, and also the formation of peroxides of hydrogen, as it is well known to those skilled in the art that plasma activation of water forms nitrates, nitrites, as well as peroxides of hydrogen.

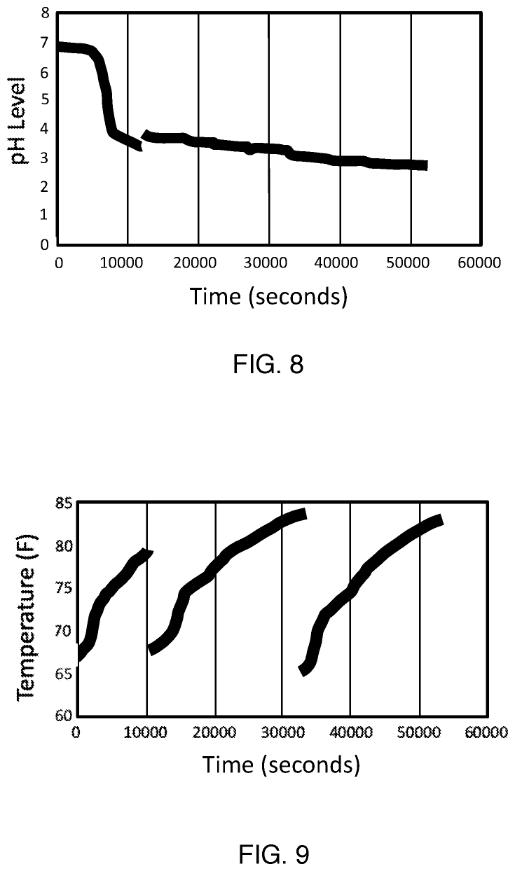

FIG. 9 shows the temporal evolution of the water temperature. In this example, the system did not use active heating or cooling, and so the temperature recovered to near room temperature between runs.

In further experiments to illustrate that the produced plasma fixated nitrogen solution has the efficacy to provide nutrients for plant growth, we have carried out three studies The first is a study on how varying concentrations of our plasma affects germination and growth of turf grass. The second is a study of how the addition of phosphorous (P) and potassium (K) added to plasma-fixated nitrogen solution impacts growth of turf grass. And the third is a comparison of how our plasma-fixated nitrogen performs against other sources of plant nitrogen of equal nitrogen content. The studies are performed by germinating and growing plants by watering with various kinds of treated water, and measuring plant growth. Plant growth is measured via plant height and dry mass.

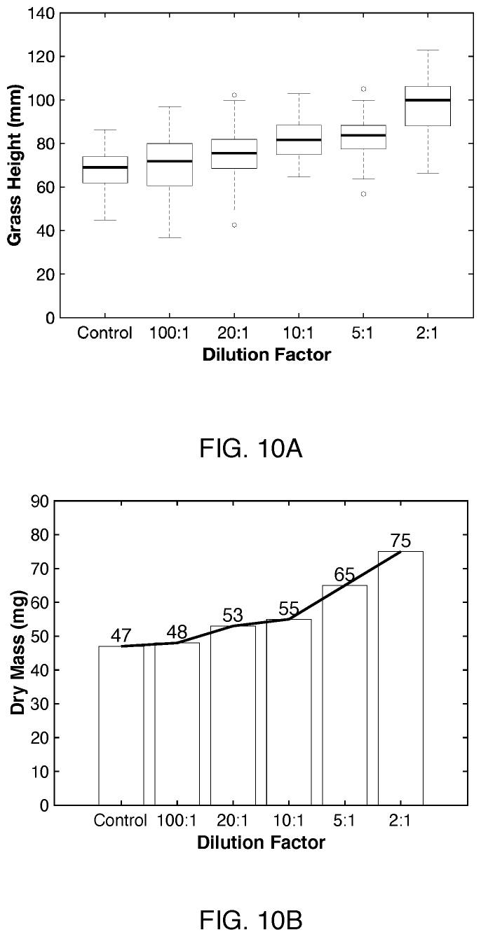

In the plasma-fixated nitrogen dilution study, 50 uniform rye-grass seeds were placed in 250 mL plastic containers on top of approximately 70 cubic centimeters of coco coir and covered with approximately 20 cubic centimeters of coco coir. For this first study, equal volumes nitrated water were added daily to each respective container. A range of dilutions of the plasma-nitrated water were prepared from a stock solution. The amount of nitrate added to each treatment group (varying dilution) over time was recorded, and final measurements were collected after 17 days following initial planting. After 17 days of growth, the turf grass with higher concentrations of plasma-fixated nitrogen (100:1, 20:1, 10:1, 5:1, 2:1 dilution ratio from the 168 ppm NO₃—N stock) were visibly taller, thicker, denser, and greener compared to the groups that received only water (control) or dilute amounts of the fertilizer (100:1 dilution). FIGS. 10A-B show the height and dry mass results, respectively, for this study.

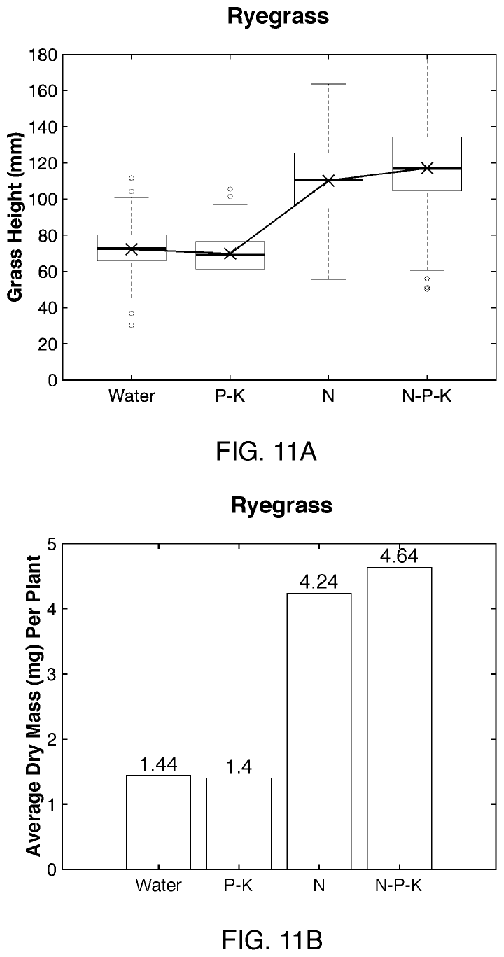

To test the effect of adding P—K to plasma-fixated nitrogen stock solution, liquid fertilizer containing only P—K (0-10-10 designation) was diluted by a factor of 1000 in industrial water. This solution was added to 168 ppm NO₃-N (nitrates as nitrogen) of plasma-fixated nitrogen stock solution to form an N—P—K complete fertilizer solution. The diluted P—K fertilizer was also tested without the added plasma-fixated nitrogen in this study as a control. 25 uniformly spaced ryegrass seeds were placed in 250 mL plastic containers on top of approximately 250 cubic centimeters of coco coir and covered with approximately a quarter inch (or about 40 cubic centimeters) of coco coir. Equal volumes of water and fertilizer solution were added daily to each respective container. The amount of nitrate added to each treatment group over time was recorded. Measurements were recorded after 19 days following initial planting. FIGS. 11A-B show the height and dry mass results, respectively, for this study. There's a clear improvement for N vs. water and for N—P—K vs. P—K.

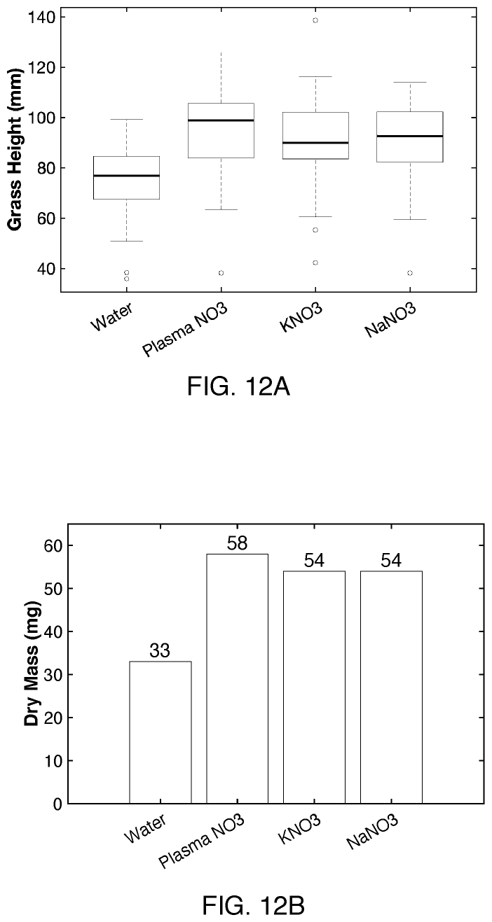

Finally, to compare the performance of plasma-fixated nitrogen in water against other sources of plant nitrogen, 5 seeds were placed in approximately 7 grams of coco coir with a quarter inch of coco coir over the seeds, and either 2.5 mL of water (control), 100 ppm NO₃—N plasma-fixated nitrogen solution, 100 ppm sodium nitrate as nitrogen (NaNO₃), purchased from ASI sensors, and 100 ppm potassium nitrate as nitrogen (KNO₃), purchased from LabChem, were added daily to each respective growth container until germination. After germination, equal volumes of the solutions were added daily to each respective treatment group. The amount of nitrate added to each treatment group over time was recorded. For all of the growth studies described here, the seeds were placed in a custom climate-controlled (T=22° C.) plant growth chamber with 24 hour light exposure during the germination period and 14 hour light exposure during post-germination and plant growth. We found that the plasma-fixated nitrogen performed as well as the other two nitrogen sources and all three of these led to improved turf growth over the nitrogen-free water control. FIGS. 12A-B show the height and dry mass results, respectively, for this study.

All three of these growth studies serve to confirm that plasma activation as described herein produces nitrogen fertilizer that improves plant growth and performs equally well as commercially-available sources of fixated nitrogen.

1. Apparatus for treating water, the apparatus comprising:
a reaction chamber having an air-water interface;
a plasma applicator disposed in air in proximity to the air-water interface, wherein the plasma applicator includes a solid dielectric plate sandwiched between a first electrode and a second electrode, wherein the first electrode is closer to the water than the second electrode, and wherein the plasma applicator further includes a first insulating layer disposed on the first electrode;
wherein the apparatus is configured to generate a plasma between the first insulating layer and the air-water interface during operation.

2. The apparatus of claim 1, wherein the apparatus is configured to provide nitrogen in water as nitrates and/or nitrites.

3. The apparatus of claim 1, wherein the apparatus is configured to acidify water.

4. The apparatus of claim 1, wherein the plasma has an electron energy range from 1 eV to 10 eV and wherein the plasma has a gas temperature of 1000° C. or less.

5. The apparatus of claim 1, wherein the first electrode is configured in a pattern selected from the group consisting of: square meshes, rectangular meshes, triangular meshes, hexagonal meshes and 1D arrays of elements.

6. The apparatus of claim 1, wherein the reaction chamber is configured as a water reservoir.

7. The apparatus of claim 1, wherein the reaction chamber is configured as a flow chamber through which water from a reservoir is pumped.

8. The apparatus of claim 1, further comprising a gas circulation system.

9. The apparatus of claim 8, wherein the gas circulation system is configured to bubble air containing activated chemical species from the plasma through the water.

10. The apparatus of claim 8, wherein the gas circulation system is configured to provide oxygenated air to the plasma.

11. The apparatus of claim 1, further comprising a heat sink affixed to the plasma applicator.

12. The apparatus of claim 11, further comprising a second insulating layer sandwiched between the second electrode and the heat sink.
